(19) United States
(12) Patent Application Publication
(10) Pub. No.: US 2026/0239600 A1
(43) Pub. Date: Aug. 13, 2026

(54) VERTICAL CHANNEL TRANSISTOR AND DRAM STRUCTURE

(71) Applicant: NANYA TECHNOLOGY CORPORATION, New Taipei City (TW)

(72) Inventor: Tseng-Fu Lu, New Taipei City (TW)

(73) Assignee: NANYA TECHNOLOGY CORPORATION, New Taipei City (TW)

(21) Appl. No.: 19/052,294

(22) Filed: Feb. 13, 2025

(51) Int. Cl. H10B 12/00

(52) U.S. Cl. CPC H10B 12/315

(57) ABSTRACT

A vertical channel transistor includes at least an oxide semiconductor pillar, a first electrode, a second electrode, a gate layer and a gate oxide layer. The oxide semiconductor pillar has a first end and a second end. The first electrode connects to the first end of the oxide semiconductor pillar, and the second electrode connects to the second end of the oxide semiconductor pillar. The gate layer surrounds a middle portion of the oxide semiconductor pillar, wherein the gate layer is made of a metal-containing barrier material which is difficult to react with oxygen. The gate oxide layer is dispose between the oxide semiconductor pillar and the gate layer.

### BACKGROUND

### Technical Field

The disclosure relates to a memory device, and particularly relates to a vertical channel transistor and a dynamic random access memory (DRAM) structure.

### Description of Related Art

To continue DRAM roadmap below 10 nm, the 4F² unit cell structure with vertical channel/pillar transistor (VCT/VPT) is proposed to replace the 6F² unit cell structure for high density and low cost requirements.

To achieve the vertical channel/pillar transistor (VCT/VPT) in 4F² DRAM, the oxide semiconductor transistor is introduced as channel material due to its extreme low leakage, large bandgap, and high electron mobility.

However, there is some problems to impact oxide semiconductor transistor performance such as Vth instability (Vth negative shift) resulting in side effects to worsen gate controllability, high unwanted off current, and low driving current.

### SUMMARY

The disclosure provides a vertical channel transistor and a DRAM structure to avoid Vth instability and to obtain high driving current.

The vertical channel transistor of the disclosure includes at least an oxide semiconductor pillar having a first end and a second end, a first electrode connected to the first end of the oxide semiconductor pillar, a second electrode connected to the second end of the oxide semiconductor pillar, a gate layer and a gate oxide layer. The gate layer surrounds a middle portion of the oxide semiconductor pillar, wherein the gate layer is made of a metal-containing barrier material which is difficult to react with oxygen. The gate oxide layer is dispose between the oxide semiconductor pillar and the gate layer.

In an embodiment of the disclosure, the oxide semiconductor pillar is vertically disposed over a substrate.

In an embodiment of the disclosure, a distance between the first electrode and the ga layer is equal to or different from a distance between the second electrode and the gate layer.

In an embodiment of the disclosure, the metal-containing barrier material comprises titanium nitride or tantalum nitride.

In an embodiment of the disclosure, the gate layer has a thickness of 20 nm or less. In an embodiment of the disclosure, the gate layer is a single layer structure.

In an embodiment of the disclosure, the vertical channel transistor further comprises an insulation structure, and the oxide semiconductor pillar, the gate oxide layer, and the gate layer are disposed in the insulation structure.

In an embodiment of the disclosure, the gate oxide layer is further disposed between the oxide semiconductor pillar and the insulation structure.

In an embodiment of the disclosure, the middle portion of the oxide semiconductor pillar has an oxygen vacancy concentration less than that of reminding portion of the oxide semiconductor pillar.

The DRAM structure of the disclosure includes at least above vertical channel transistor and a storage device coupled with the vertical channel transistor.

In another embodiment of the disclosure, the storage device comprises a capacitor.

Based on the above, according to the vertical channel transistor of the disclosure, the gate layer is made of a barrier material for preventing oxygen from diffusing out of the middle of the oxide semiconductor, thereby improve threshold voltage (Vth) stability. Moreover, the upper and lower ends of the oxide semiconductor have oxygen vacancies to reduce the resistivity at the interface between the oxide semiconductor and two electrodes.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates a plan view of a plurality of vertical channel transistors in accordance with some embodiments of the present disclosure.

FIG. 2 illustrates a cross-sectional view of the vertical channel transistors of FIG. 1.

FIG. 3 illustrates a cross-sectional view of the vertical channel transistors of FIG. 2 after a high temperature (HT) process.

FIG. 4 illustrates a cross-sectional view of a DRAM structure in accordance with some embodiments of the present disclosure.

### DESCRIPTION OF THE EMBODIMENTS

With reference to the drawings attached, the disclosure will be described by means of the embodiments below. Nevertheless, the disclosure may be embodied in many different forms and should not be construed as limited to the embodiments set forth herein. In the drawings, for the purpose of clarity and specificity, the sizes and the relative sizes of each layer and region may not be illustrated in accurate proportion.

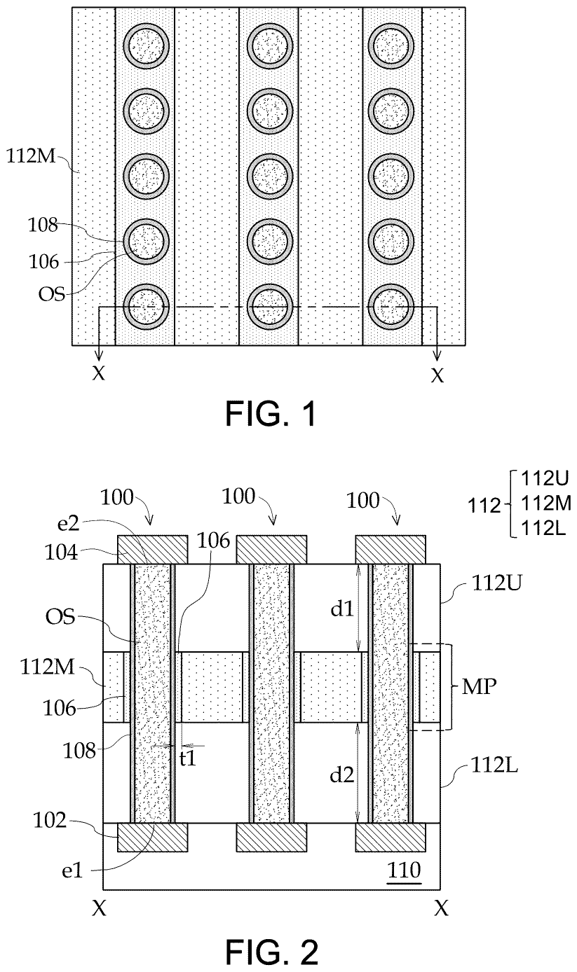

FIG. 1 illustrates a plan view of a plurality of vertical channel transistors in accordance with some embodiments of the present disclosure, and FIG. 2 illustrates a cross-sectional view of the vertical channel transistors of FIG. 1. For clarity, some elements in FIG. 1 are not shown such as the upper portion 112 and the second electrode 104 in FIG. 2.

Referring now to FIGS. 1 and 2, each vertical channel transistor 100 includes at least oxide semiconductor pillar OS having a first end e1 and a second end e2, a first electrode 102 connected to the first end e1 of the oxide semiconductor pillar OS, a second electrode 104 connected to the second end e2 of the oxide semiconductor pillar OS, a gate layer 106 and a gate oxide layer 108. In some embodiments, the oxide semiconductor pillar OS is vertically disposed over a substrate 110. In some embodiments, a material of the oxide semiconductor pillar OS may be at least one of indium gallium zinc oxide (IGZO), manganese oxide (MnO₂), zinc oxide (ZnO), indium zinc oxide (IZO), indium tin zinc oxide (ITZO) and the like, and no limitation is made to the present disclosure herein.

The gate layer 106 surrounds a middle portion MP of the oxide semiconductor pillar OS, wherein the middle portion MP may be the central part of the oxide semiconductor pillar OS that occupies one third of the height. In some embodiments, a height of the gate layer 106 is less than that of the middle portion MP, but it is not limited thereto. The gate layer 106 is made of a metal-containing barrier material which is difficult to react with oxygen. For example, the metal-containing barrier material comprises titanium nitride or tantalum nitride. The gate layer 106 shown in FIG. 1 may be also utilized as a word line for the vertical channel transistors 100. The gate oxide layer 108 is dispose between the oxide semiconductor pillar OS and the gate layer 106. In some embodiments, the vertical channel transistor 100 further comprises an insulation structure 112. The oxide semiconductor pillar OS, the gate oxide layer 108, and the gate layer 106 may be disposed in the insulation structure 112. In some embodiments, the gate oxide layer 108 is also disposed between the oxide semiconductor pillar OS and the insulation structure 112. In some embodiments, the gate layer 106 has a thickness t1 of 20 nm or less; for instance, 15 nm or less. The “thickness t1” represents a dimension of the gate layer 106 perpendicular to the extension direction of the oxide semiconductor pillar OS. According to research, if the thickness t1 of titanium nitride is less than a certain level, its conductivity will be the same as or higher than that of metal (e.g. tungsten) with the same thickness. Therefore, the metal-containing barrier material can indeed be utilized as a gate of the vertical channel transistor 100. In some embodiments, the gate layer 106 is a single layer structure, and it means that the gate layer 106 does not contain other layers but only the metal-containing barrier material.

In some embodiments, a distance d2 between the first electrode 102 and the gate layer 106 is different from a distance d1 between the second electrode 104 and the gate layer 106. For example, the distance d1 is shorter than the distance d2, or the distance d1 is larger than the distance d2. In some embodiments, a distance d2 between the first electrode 102 and the gate layer 106 is equal to a distance d1 between the second electrode 104 and the gate layer 106.

In some embodiments, the insulation structure 112 includes a lower insulation layer 112L, an intermediate insulation layer 112M, and an upper insulation layer 112U staked in sequence. The gate layer 106 may be disposed in the intermediate insulation layer 112M, and a material of the intermediate insulation layer 112M comprises oxide or other suitable insulation materials.

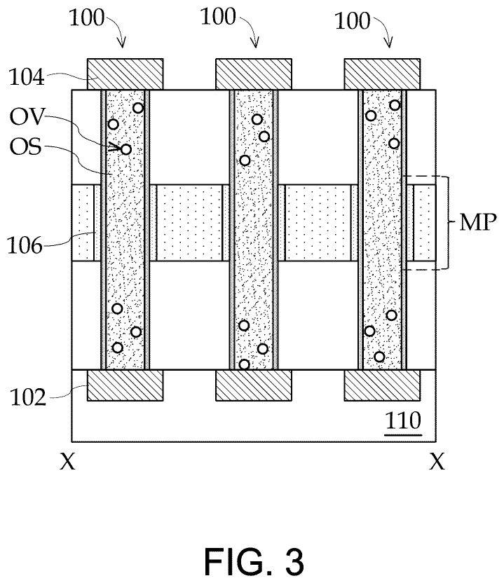

In some embodiments, the middle portion MP of the oxide semiconductor pillar OS has an oxygen vacancy concentration less than that of reminding portion of the oxide semiconductor pillar OS as shown in FIG. 3. In FIG. 3, the vertical channel transistors 100 undergo a high temperature (HT) process such as hydrogen/chlorine/fluorine species related processes in order to lower resistance of the top of the oxide semiconductor pillar OS, and the oxygen out diffusion phenomenon at two ends of the oxide semiconductor pillar OS are happened and the oxygen vacancy OV are generated. Since oxygen vacancy can help in creating the space in the lattice for the elements to move when electric field is applied, it can help to reduce the channel resistance and more driving current is expected. On the other hand, due to the gate layer 106 (made of the metal-containing barrier material), oxygen would not or be hard to diffuse out the oxide semiconductor pillar OS, and thus the middle portion MP has no or less oxygen vacancy. Accordingly, Vth (threshold voltage) may become stable when the gate layer 106 with barrier function for preventing the occurrence of oxygen vacancy.

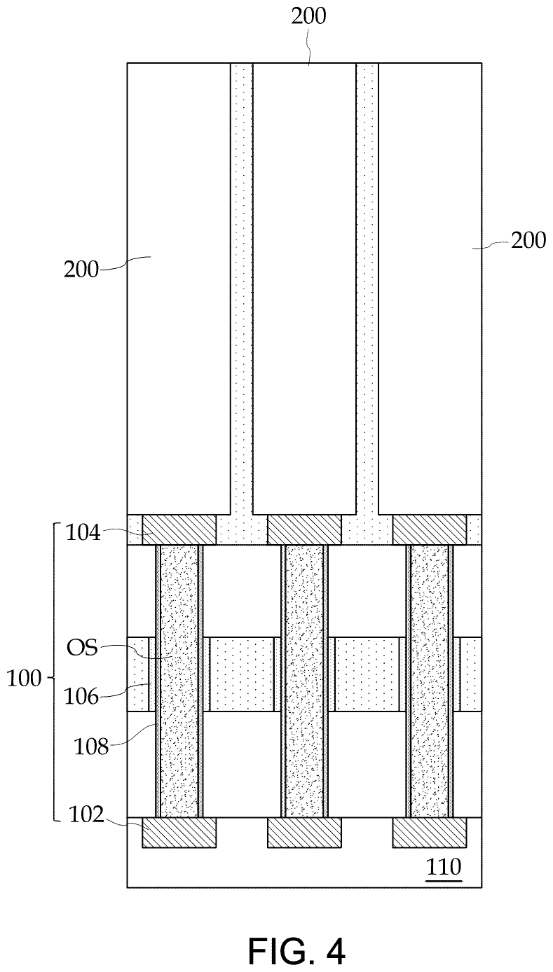

FIG. 4 illustrates a cross-sectional view of a DRAM structure in accordance with some embodiments of the present disclosure.

Referring to FIG. 4, a DRAM structure includes the vertical channel transistor 100 of above embodiment and a storage device 200 coupled with the vertical channel transistor 100. In some embodiment, the second electrode 104 of the vertical channel transistor 100 is connected to the storage device 200, and the first electrode 102 of the vertical channel transistor 100 may be connected to a bit line (not shown) or the storage device 200 via an interconnect (not shown). In some embodiment, the storage device 200 comprises a capacitor. The DRAM structure, for instance, uses a 1T1C memory cell, where 1T is shown as the vertical channel transistor 100, and 1C is shown as the capacitor (the storage device 200). In some embodiment, the capacitor may include two conductive layers (not shown) and a capacitive medium layer therebetween, and the capacitive medium layer (not shown) and the two conductive layers may form a cylindrical structure. However, the disclosure is not limited thereto.

In summary, since gate layer with barrier function, oxygen out diffusion phenomenon at gate surrounding portion will be prevented. Therefore, there is no generated oxygen vacancy and the Vth is stable (without negative shift). On the other hand, oxygen out diffusion phenomenon at the other portions (channel top and channel bottom) are happened and the oxygen vacancy are generated so as to help to reduce channel resistance and more driving is expected.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A vertical channel transistor, comprising:
an oxide semiconductor pillar having a first end and a second end;
a first electrode connected to the first end of the oxide semiconductor pillar;
a second electrode connected to the second end of the oxide semiconductor pillar;
a gate layer surrounding a middle portion of the oxide semiconductor pillar, wherein the gate layer is made of a metal-containing barrier material which is difficult to react with oxygen; and
a gate oxide layer dispose between the oxide semiconductor pillar and the gate layer.

2. The vertical channel transistor of claim 1, wherein the oxide semiconductor pillar is vertically disposed over a substrate.

3. The vertical channel transistor of claim 1, wherein a distance between the first electrode and the gate layer is equal to a distance between the second electrode and the gate layer.

4. The vertical channel transistor of claim 1, wherein a distance between the first electrode and the gate layer is different from a distance between the second electrode and the gate layer.

5. The vertical channel transistor of claim 1, wherein the metal-containing barrier material comprises titanium nitride or tantalum nitride.

6. The vertical channel transistor of claim 1, wherein the gate layer has a thickness of 20 nm or less.

7. The vertical channel transistor of claim 1, further comprising an insulation structure, and the oxide semiconductor pillar, the gate oxide layer, and the gate layer are disposed in the insulation structure.

8. The vertical channel transistor of claim 7, wherein the gate oxide layer is further disposed between the oxide semiconductor pillar and the insulation structure.

9. The vertical channel transistor of claim 1, wherein the middle portion of the oxide semiconductor pillar has an oxygen vacancy concentration less than that of reminding portion of the oxide semiconductor pillar.

10. The vertical channel transistor of claim 1, wherein the gate layer is a single layer structure.

11. A DRAM structure, comprising:
the vertical channel transistor of claim 1; and
a storage device coupled with the vertical channel transistor.

12. The DRAM structure of claim 11, wherein the storage device comprises a capacitor.
